(19) United States
(12) Patent Application Publication
(10) Pub. No.: US 2012/0081877 A1
(43) Pub. Date: Apr. 5, 2012

(54) DISPLAY DEVICE AND COVER OF ELECTRONIC DEVICE

(75) Inventors: Kuo-Nan Ling, Taipei City (TW); Po-An Lin, Taipei City (TW); Yung-Hui Chen, Taipei City (TW)

(73) Assignee: COMPAL ELECTRONICS, INC., Taipei City (TW)

(21) Appl. No.: 13/279,347

(22) Filed: Oct. 24, 2011

Related U.S. Application Data
(63) Continuation-in-part of application No. 13/171,482, filed on Jun. 29, 2011.
(60) Provisional application No. 61/359,811, filed on Jun. 29, 2010.
(60) Provisional application No. 61/421,219, filed on Dec. 9, 2010.

(51) Int. Cl. H05K 5/03; H05K 5/00

(52) U.S. Cl. 361/807; 174/50

(57) ABSTRACT

A display device includes a frame, a display module, and a cover. The display module is adhered in the frame. The cover is fixed with the frame, and the cover includes a first housing, a second housing, and a connecting element, wherein the first housing and the second housing are form to a cover plate, and the connecting element is disposed overlap on the first housing and the second housing to increase the strength of the cover plate.

### CROSS-REFERENCE TO RELATED APPLICATION

This application is a continuation-in-part application of and claims the priority benefit of a prior application Ser. No. 13/171,482, filed on Jun. 29, 2011, now pending. The prior application Ser. No. 13/171,482 claims the priority benefit of provisional application Ser. No. 61/359,811, filed on Jun. 29, 2010. This application also claims the priority benefit of provisional application Ser. No. 61/421,219, filed Dec. 9, 2010. The entirety of each of the above-mentioned patent applications is hereby incorporated by reference herein and made a part of this specification.

### BACKGROUND OF THE INVENTION

1. Field of the Invention

The invention relates to an electronic device. More particularly, the invention relates to a cover of an electronic device.

2. Description of Related Art

Along with development of semiconductor devices and display techniques, electronic products are continually developed towards miniaturization, multi-functionality, and portability. The common portable electronic products include notebook computers, tablet computers, mobile phones, etc. The notebook computer is, for instance, constituted by a host and a display device pivotally connected to each other. A user is allowed to close the host and the display device of the notebook computer in order for the notebook computer to be portable. When the notebook computer is to be used, the display device can be opened by pivoting the display device relative to the host to facilitate operation and observation of the display images.

FIG. 1 illustrates a cover 1 of an electronic device. The cover 1 can hold a display module (not shown) for display images. In the electronic device, an antenna module (not shown) is often configured between the display module and the cover, such that the electronic device can have wireless connection.

At present, the cover 1 is frequently made of metal (e.g., aluminum), such that the entire weight of the housing 1 is reduced, and the metallic cover 1 can satisfy the requirement for the embellished exterior of the electronic device. The cover 1 often has a first housing 11 and a second housing 12. The first housing 11 is made of aluminum, and the second housing 12 is made of plastic. The second housing 12 is configured corresponding to the antenna module, so as to prevent the metal material of the first housing 11 from affecting the operation of the antenna module in the cover 1.

With reference to FIG. 2, a bent connection portion 121 is located at a side of the second housing 12, and the connection portion 121 of the second housing 12 overlaps the back side of the first housing 11. As indicated in FIG. 2, the total thickness T1 of the overlapping portion of the first housing 11 and the second housing 12 is greater than the thickness of the first housing 11 or the thickness of the second housing 12, which is detrimental to miniaturization of the housing 1 of the electronic device.

### SUMMARY OF THE INVENTION

In view of the above, a display device that has a frame, a display module, and a cover is provided. The display module is adhered to the frame. The cover is fixed to the frame and has a first housing, a second housing, and a connection element. The first housing and the second housing form a cover plate, and the connection element overlaps and fixes both the first housing and the second housing to increase the strength of the cover plate.

According to an embodiment of the invention, the second housing has a main portion and a connection portion. A thickness of the connection portion is smaller than a thickness of the main portion. A thickness of the first housing is approximately equal to the thickness of the connection portion. The connection element overlaps both the connection portion and the first housing.

According to an embodiment of the invention, a total thickness of an overlapping portion of the connection element and the connection portion and an overlapping portion of the connection element and the first housing is approximately equal to a thickness of the second housing.

According to an embodiment of the invention, the second housing further has a concave portion that communicates with the connection portion. The connection element has a protrusion. When the connection element overlaps both the connection portion and the first housing, the protrusion overlaps the concave portion.

According to an embodiment of the invention, the first housing has a main portion and a connection portion. A thickness of the connection portion is smaller than a thickness of the main portion. A thickness of the second housing is approximately equal to the thickness of the connection portion. The connection element overlaps both the connection portion and the second housing.

According to an embodiment of the invention, a total thickness of an overlapping portion of the connection element and the connection portion and an overlapping portion of the connection element and the second housing is smaller than or equal to a thickness of the first housing or a thickness of the second housing.

According to an embodiment of the invention, the first housing further has a concave portion that communicates with the connection portion. The connection element has a protrusion. When the connection element overlaps both the connection portion and the second housing, the protrusion overlaps the concave portion.

According to an embodiment of the invention, the connection element is adhered to and overlaps both the first housing and the second housing.

According to an embodiment of the invention, a material of the first housing is metal, and a material of the second housing is plastic.

According to an embodiment of the invention, the housing of the electronic device is a cover of a display module.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic view illustrating a cover of a conventional electronic device;

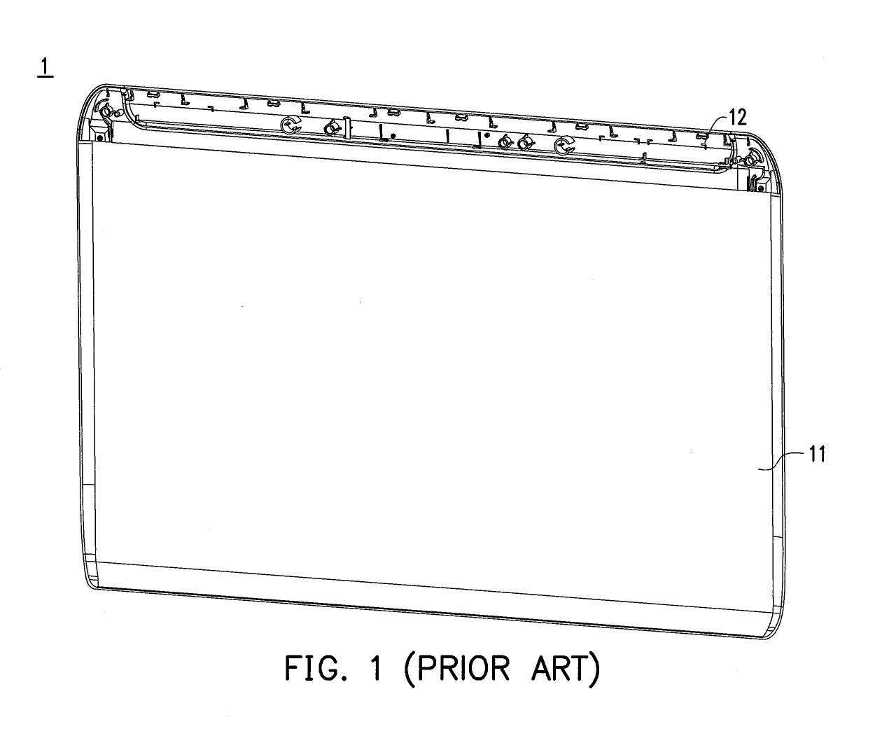

FIG. 2 is another schematic view illustrating a cover of a conventional electronic device;

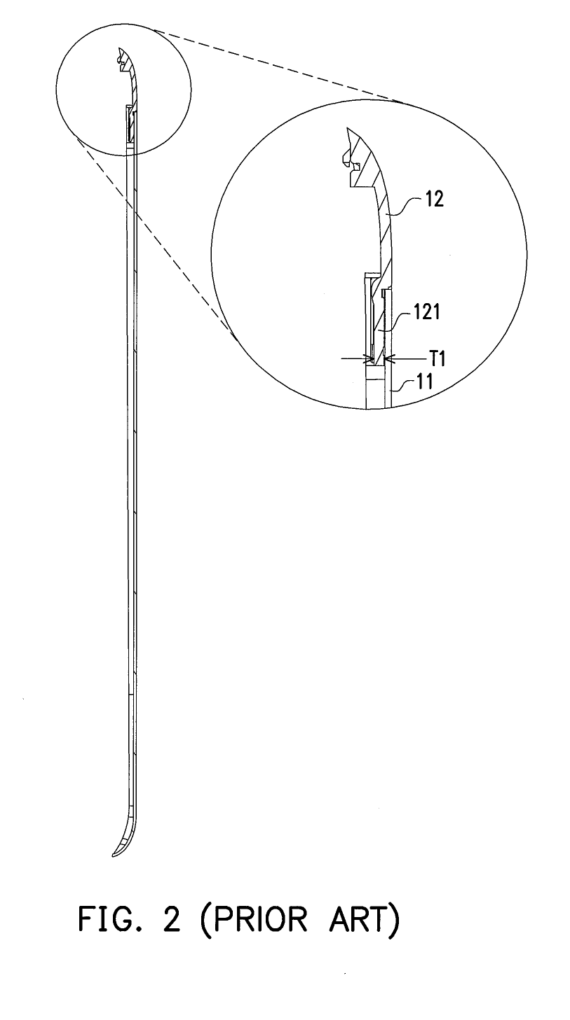

FIG. 3 is a three-dimensional exploded view illustrating a display device according to an embodiment of the invention;

FIG. 4 is a schematic view illustrating a display device according to an embodiment of the invention;

FIG. 5 is a schematic view illustrating a cover of a display device according to an embodiment of the invention;

FIG. 6 is a three-dimensional exploded view illustrating a cover of a display device according to an embodiment of the invention; and

FIG. 7 is another schematic view illustrating a cover of a display device according to an embodiment of the invention.

### DESCRIPTION OF EMBODIMENTS

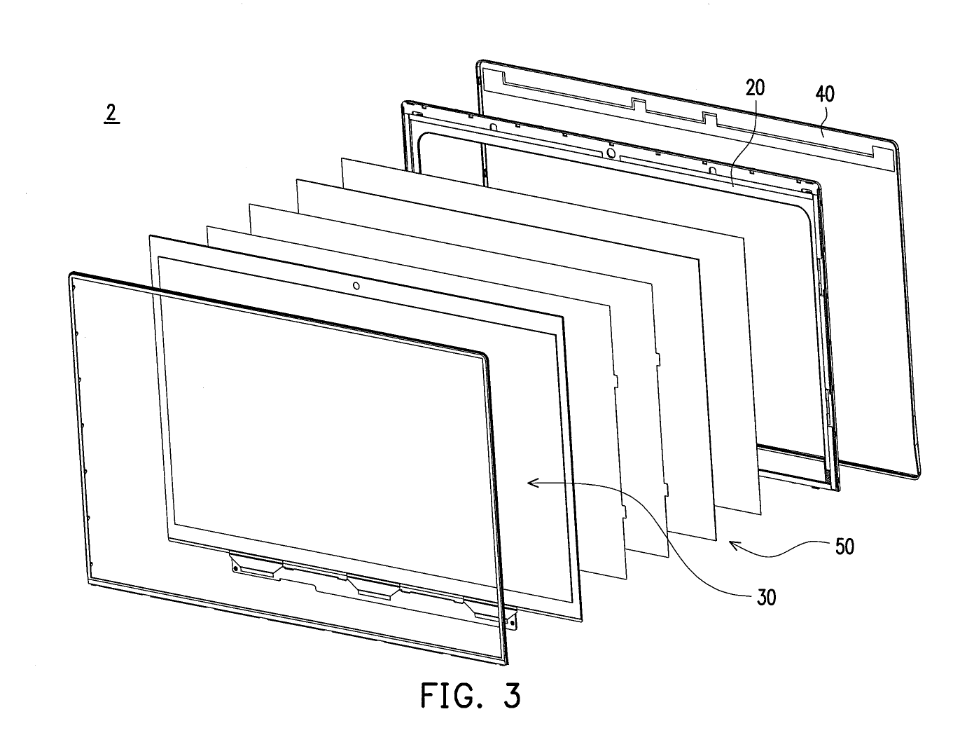

FIG. 3 is a schematic view illustrating a display device 2 according to an embodiment of the invention. The display device 2 includes a frame 20, a display module 30, and a cover 40. In this invention, if the display device 2 is in a liquid crystal display (LCD), the display device 2 further includes a backlight module 50. If the display device is in an organic light-emitting diode (OLED) display, for instance, the display device is not equipped with the backlight module. The display device 2 described in the embodiments of the invention is a display of a notebook computer. Certainly, the display device 2 of the invention is also applicable to a tablet computer, a mobile phone, a television, and so forth.

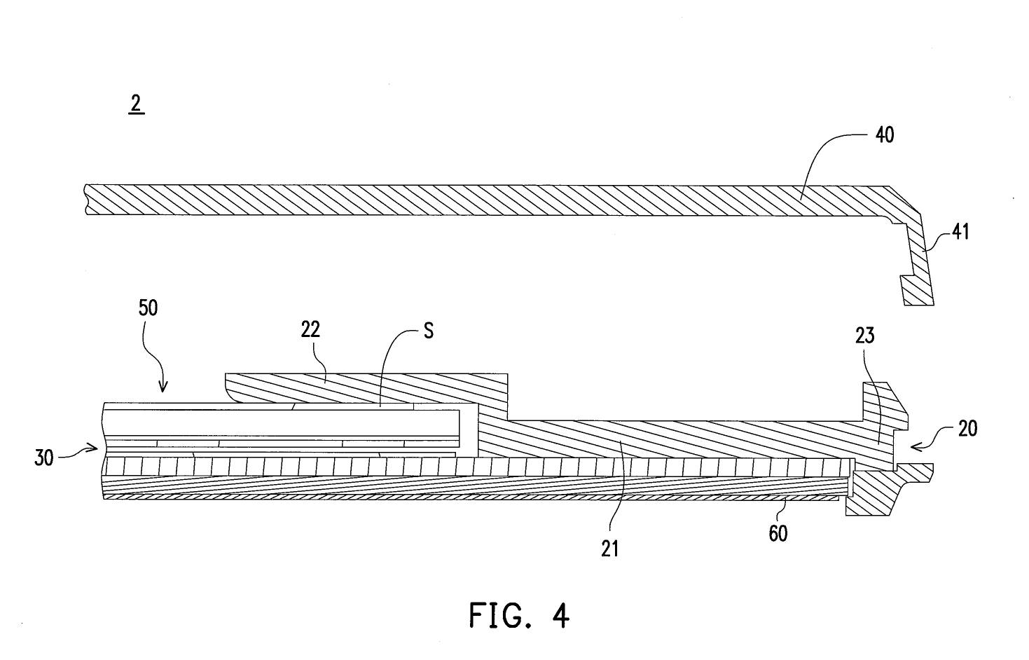

With reference to FIG. 4, the frame 20 has a first supporting portion 21 and a second supporting portion 22. A glass panel 60 is adhered to the first supporting portion 21, such that a user is allowed to observe the images displayed by the display module 30 through the glass panel 60. The glass panel 60 also protects the display module 30. When the display device 2 has the backlight module 50, the backlight module 50 is adhered to the second supporting portion 22. By contrast, when the display device 2 does not have the backlight module, the display module 30 is directly adhered to the second supporting portion 22. In this embodiment, the display module 30 is adhered to the frame 20 by an adhesive S, and a material of the adhesive S can include epoxy resin.

As shown in FIG. 4, the cover 40 has a first lock portion 41, and the frame 20 has a second lock portion 23. The first lock portion 41 and the second lock portion 23 can be locked to each other, such that the cover 40 can be fixed to the frame 20. Based on the above, no addition space needs to be reserved for screwing the display module 30 to the cover 40. Instead, the display module 30 can be fixed to the cover 40 by locking the first lock portion 41 and the second lock portion 23, such that the entire display device 2 can have a relatively thin thickness.

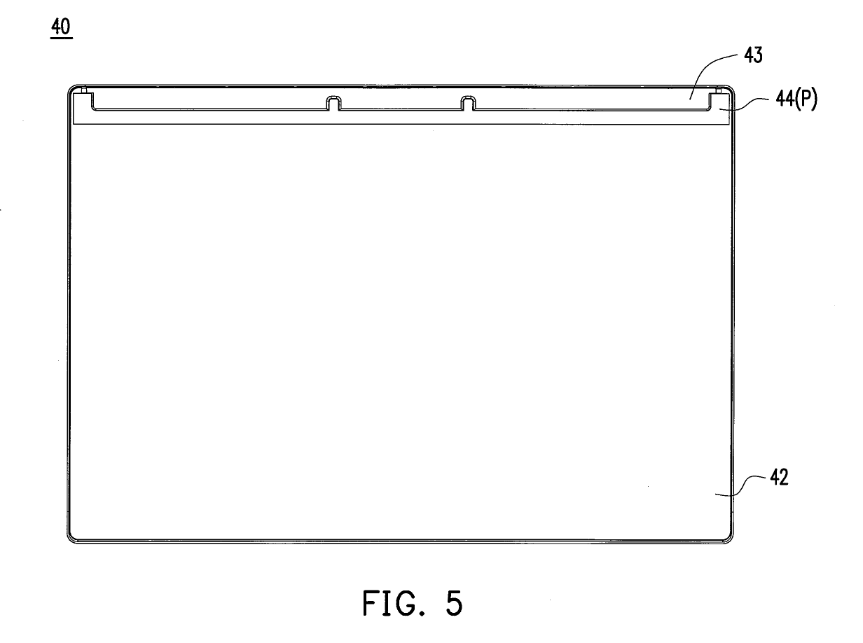

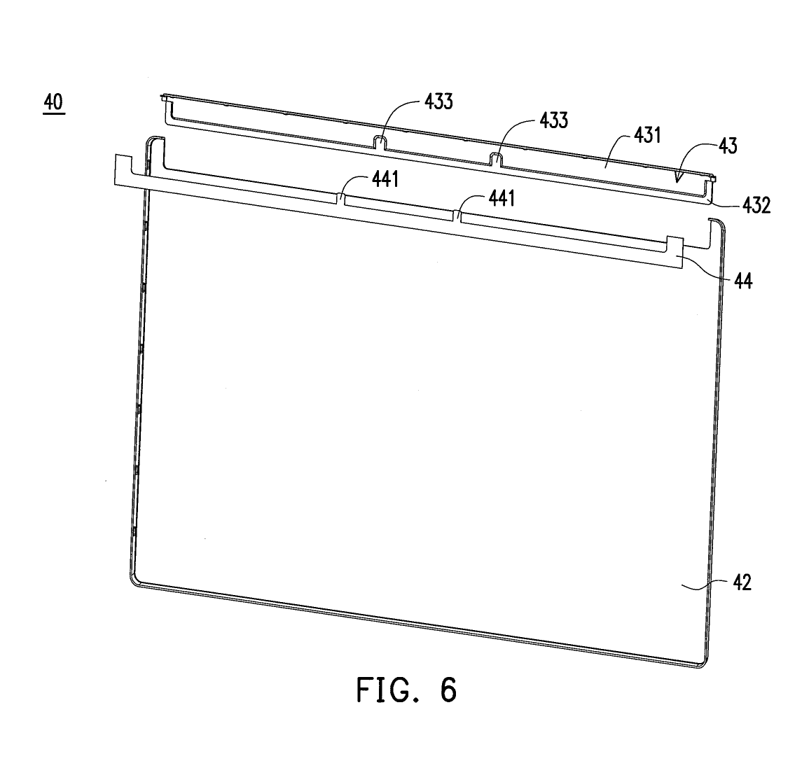

With reference to FIG. 5, the cover 40 of the display device described in the embodiment of the invention has a first housing 42, a second housing 43, and a connection element 44. The second housing 43 is configured at one side of the first housing 42, and the second housing 43 and the first housing 42 form a cover plate P. The connection element 44 overlaps and fixes both the first housing 42 and the second housing 43, so as to increase the strength of the cover plate P. With reference to FIG. 6, the second housing 43 has a main portion 431 and a connection portion 432, and the thickness of the connection portion 432 is smaller than the thickness of the main portion 431, as indicated in FIG. 6. The first housing 42 is configured alongside the connection portion 432 to form the cover plate P. In this embodiment, the first housing 42 is made of aluminum, and the second housing 43 is made of plastic. Undoubtedly, the materials of the first and second housings 42 and 43 are not limited in the invention and can be determined based on actual requirements.

As shown in FIG. 6, the second housing 43 further has two concave portions 433 that communicate with the connection portion 432. The connection element 44 has two protrusions 441, and each of the protrusions 441 respectively corresponds to one of the concave portions 433. When the connection element 44 overlaps the connection portion 432 and the first housing 42, each of the protrusions 441 is respectively configured in and stacked on one of the concave portions 433. Owing to the configuration of the concave portions 433 and the protrusions 441, the bonding strength of the connection element 44 and the first and second housings 42 and 43 can be enhanced. The number of the concave portions 433 is two, and so is the number of the protrusions 441 in this embodiment, for instance. Note that the number of the concave portions 433 and the protrusions 441 can be adjusted based on actual requirements.

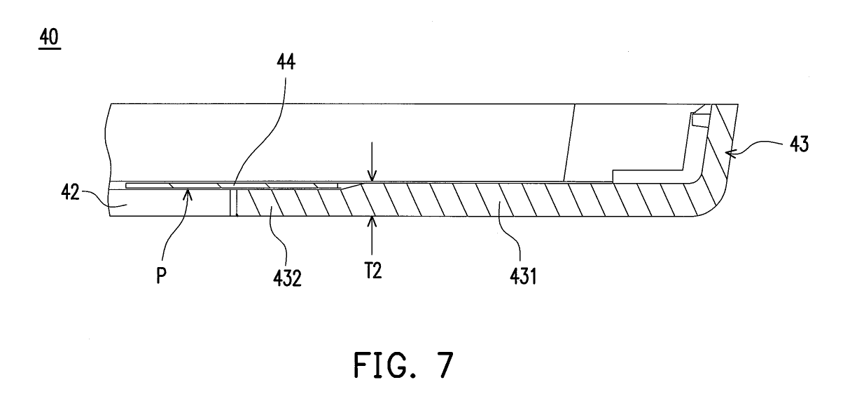

With reference to FIG. 7, the thickness of the connection portion 432 is smaller than the thickness of the main portion 431 of the second housing 43, and the thickness of the first housing 42 is approximately equal to the thickness of the connection portion 432. When the connection element 44 overlaps the connection portion 432 and the first housing 42, the overlapping portion of the connection element 44 and the connection portion 432 and the overlapping portion of the connection element 44 and the first housing 42 have a total thickness T2, and the total thickness T2 is approximately equal to the thickness of the second housing 43. Besides, the total thickness T2 is smaller than or equal to the thickness of the first housing 42 or the thickness of the second housing 43. Accordingly, the requirement for miniaturizing the cover 40 of the entire display device can be satisfied.

In this embodiment, the connection element 44 directly overlaps and is adhered to the first housing 42 and the connection portion 432 of the second housing 43. The material of the connection element 44 has greater strength than the material of the first and second housings 42 and 43, and the cover 40 can be assembled after the connection element 44 directly overlaps and is adhered to the first and second housings 42 and 43. Hence, the assembly is easy and can satisfy the requirement for miniaturization because the assembly does not require additional locking or latching structure.

Certainly, the invention is not limited thereto. The connection portion can also be configured at the first housing. At this time, the thickness of the connection portion of the first housing is smaller than the thickness of the main portion of the first housing. When the connection element overlaps both the connection portion and the second housing, the overlapping portion of the connection element and the connection portion and the overlapping portion of the connection element and the second housing have a total thickness, and the total thickness is smaller than or equal to the thickness of the first housing or the thickness of the second housing.

With reference to FIG. 5 to FIG. 7, a cover of an electronic device includes a first housing 42, a second housing 43, and a connection element 44 according to another embodiment of the invention. The cover of the electronic device as described in this embodiment is the same as the cover 40 of the display device 2 described in the previous embodiments, i.e., the cover of this embodiment also has the first housing 42, the second housing 43, and the connection element 44. Therefore, the same elements are labeled by the same reference numbers and will not be reiterated hereinafter.

In light of the foregoing, the connection element in the display device and the housing of the electronic device has favorable material strength. After the first and second housings form the cover plate, the connection element overlaps the first and second housings to increase the strength of the cover plate. Thereby, the housing of the electronic device or the cover of the display device can be assembled. In comparison with the conventional structure, the first and second housings described in the embodiments of the invention are not overlapped to each other, and the total thickness of the overlapping portion of the connection element and the first and second housings is smaller than or equal to the thickness of the first housing or the thickness of the second housing. Accordingly, the requirement for miniaturization can indeed be satisfied. Moreover, the frame and the display module are adhered to each other, and the cover is fixed to the frame to complete the assembly of the display device. No addition space needs to be reserved for screwing the display module to the cover, such that the entire display device can have a relatively thin thickness. Besides, it is not necessary to configure a threaded hole on the display module, and thus the display module can have a relative large display area.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A cover of an electronic device, comprising:
a first housing;
a second housing, the first housing and the second housing forming a cover plate; and
a connection element overlapped and fixed to both the first housing and the second housing to increase strength of the cover plate.

2. The cover of the electronic device as recited in claim 1, wherein the second housing has a main portion and a connection portion, a thickness of the connection portion is smaller than a thickness of the main portion, a thickness of the first housing is approximately equal to the thickness of the connection portion, and the connection element overlaps both the connection portion and the first housing.

3. The cover of the electronic device as recited in claim 2, wherein a total thickness of an overlapping portion of the connection element and the connection portion and an overlapping portion of the connection element and the first housing is approximately equal to a thickness of the second housing.

4. The cover of the electronic device as recited in claim 2, wherein the second housing further has a concave portion, the concave portion communicates with the connection portion, the connection element has a protrusion, and the protrusion overlaps the concave portion when the connection element overlaps both the connection portion and the first housing.

5. The cover of the electronic device as recited in claim 1, wherein the first housing has a main portion and a connection portion, a thickness of the connection portion is smaller than a thickness of the main portion, a thickness of the second housing is approximately equal to the thickness of the connection portion, and the connection element overlaps both the connection portion and the second housing.

6. The cover of the electronic device as recited in claim 5, wherein a total thickness of an overlapping portion of the connection element and the connection portion and an overlapping portion of the connection element and the second housing is smaller than or equal to a thickness of the first housing or the thickness of the second housing.

7. The cover of the electronic device as recited in claim 5, wherein the first housing further has a concave portion, the concave portion communicates with the connection portion, the connection element has a protrusion, and the protrusion overlaps the concave portion when the connection element overlaps both the connection portion and the second housing.

8. The cover of the electronic device as recited in claim 1, wherein the connection element is adhered to and overlaps both the first housing and the second housing.

9. The cover of the electronic device as recited in claim 1, wherein a material of the first housing is metal, and a material of the second housing is plastic.

10. A display device comprising:
a frame;
a display module adhered to the frame; and
a cover fixed to the frame and having a first housing, a second housing, and a connection element, wherein the first housing and the second housing form a cover plate, and the connection element overlaps and fixes to both the first housing and the second housing to increase strength of the cover plate.

11. The display device as recited in claim 10, wherein the cover has a first lock portion, the frame has a second lock portion, and the first portion and the second portion are locked to each other to fix the cover to the frame.

12. The display device as recited in claim 10, further comprising a glass panel, the frame having a first supporting portion, the glass panel being adhered to the first supporting portion.

13. The display device as recited in claim 10, wherein the frame has a second supporting portion, and the display module is adhered to the second supporting portion.

14. The display device as recited in claim 10, further comprising a backlight module configured at a side of the display module.

15. The display device as recited in claim 14, wherein the frame has a second supporting portion, and the backlight module is adhered to the second supporting portion.

16. The display device as recited in claim 10, wherein the second housing has a main portion and a connection portion, a thickness of the connection portion is smaller than a thickness of the main portion, a thickness of the first housing is approximately equal to the thickness of the connection portion, and the connection element overlaps both the connection portion and the first housing.

17. The display device as recited in claim 16, wherein a total thickness of an overlapping portion of the connection element and the connection portion and an overlapping portion of the connection element and the first housing is approximately equal to a thickness of the second housing.

18. The display device as recited in claim 16, wherein the second housing further has a concave portion, the concave portion communicates with the connection portion, the connection element has a protrusion, and the protrusion overlaps the concave portion when the connection element overlaps both the connection portion and the first housing.

19. The display device as recited in claim 10, wherein the first housing has a main portion and a connection portion, a thickness of the connection portion is smaller than a thickness of the main portion, a thickness of the second housing is approximately equal to the thickness of the connection portion, and the connection element overlaps both the connection portion and the second housing.

20. The display device as recited in claim 19, wherein the first housing further has a concave portion, the concave portion communicates with the connection portion, the connection element has a protrusion, and the protrusion overlaps the concave portion when the connection element overlaps both the connection portion and the second housing.
